(19) United States
(12) Patent Application Publication
(10) Pub. No.: US 2011/0291607 A1
(43) Pub. Date: Dec. 1, 2011

(54) Case or Other Portable Container With at Least One Electric Power Supply and Storage Unit Which can be Recharged Using Solar Energy or Other Energy Sources, Useful for Providing Electric Power During Open-Air Activities or for Other Uses

(76) Inventors: Enea Afro Rossi, NOVI DI MODENA (IT); Demis Fabbri, NOVI DI MODENA (IT)

(21) Appl. No.: 13/108,422

(22) Filed: May 16, 2011

(30) Foreign Application Priority Data
May 25, 2010 (IT) BO2010U000055

(51) Int. Cl. H02J 7/00; A45F 3/00; H01L 31/045

(52) U.S. Cl. 320/101; 136/245; 224/600

(57) ABSTRACT

Case or other portable container with an electric power supply and storage unit which can be recharged using solar energy or other energy sources, useful for providing electric power during open-air activities or for other uses, of the type which comprises a case or other preferably rigid or semi-rigid container (1), with the base body (101) and the lid (201) designed internally to house at least one solar panel and at least one electric power supply and storage unit (6) which can be recharged by means of said solar panel and which is provided with sockets so as to be able to supply electric user applications, characterized in that several solar panels (4) which can be folded in book form and wallet form are housed inside the said case (1) so that in the folded position the panels occupy an extremely small amount of space and in the open position the panels have a much larger exposed area, all of which being envisaged so that, also owing to the fact that more than one of the solar panels (4) is available, it is possible to reduce substantially the recharging time of the supply and storage unit (6) and this unit may be used with a capacity such as to ensure good autonomy and safe operation thereof.

The invention relates to a case or other portable container, containing at least one electric power supply and storage unit with a high capacity and therefore sufficient autonomy, designed to be recharged using solar panels or other energy sources and in particular suitable for providing electric power during open-air activities, for example for powering lamps, a television, a computer or other low-power user applications.

By way of prior art the following patent application publications are cited: CN 2251803 dated Sep. 4, 1997 (Portable solar energy electrical equipment combined box with warning circuit); US 2008/0210289 dated Apr. 9, 2008 (Portable solar power source); WO 2009/045542 dated Sep. 4, 2009 (Electrical power source), to which ample reference is made. All these documents show that it is currently known to combine with a case or a rucksack solar panels and a high-capacity electric power supply and storage unit which can be recharged by means of the said solar panels or using other energy sources in order to provide electric power for various uses during open-air activities. These known apparatus are, however, characterized by the long time needed to recharge them via the solar panels since the latter have a limited exposure area owing to a combined arrangement which is structurally dependent on a part of the surface of the case or rucksack and therefore is conditioned by the dimensions of the case itself.

The invention intends to overcome these and other limitations of the prior art with a portable device as per the accompanying claim 1, the characteristic features and the advantages of which will become clear from the following description provided with reference to the two accompanying sets of drawings in which:

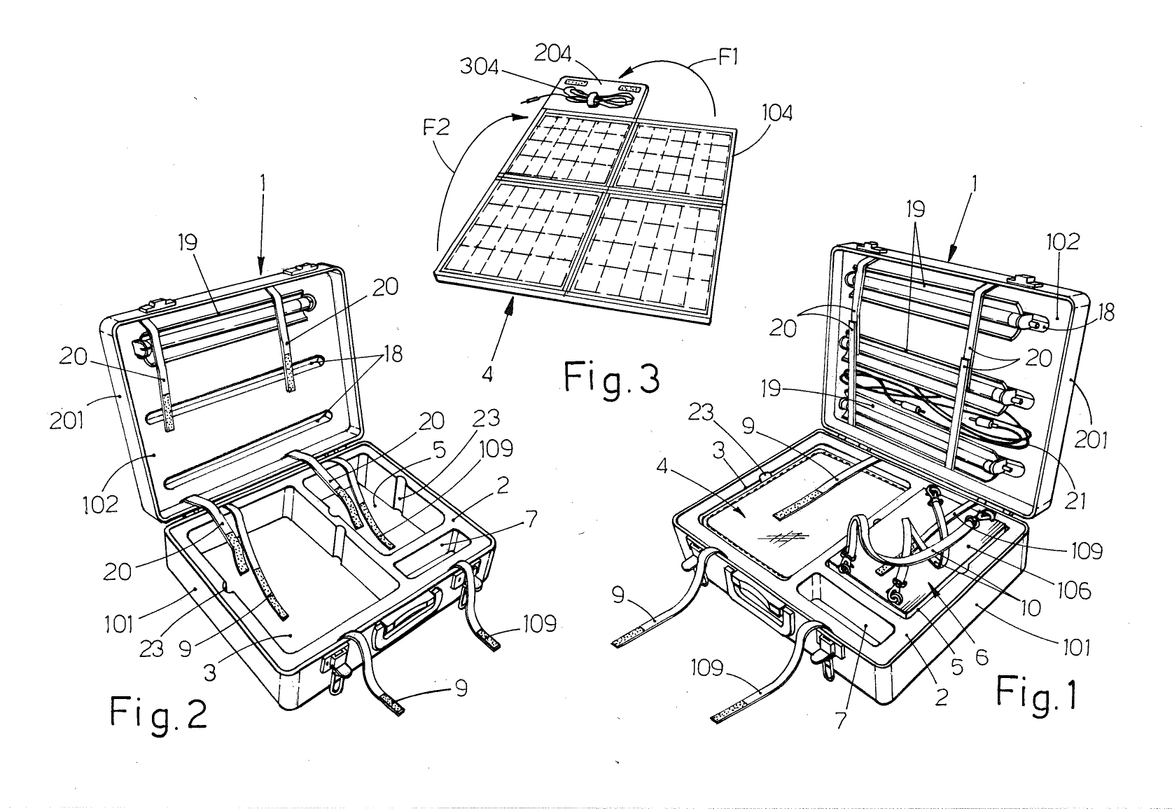

FIG. 1 shows a perspective view of the case open with inside the various components;

FIG. 2 shows a perspective view of the case open as in FIG. 1, emptied of the various components, except for a lamp holder;

FIG. 3 shows, in an extended position ready for use, one of the solar panels housed inside the case;

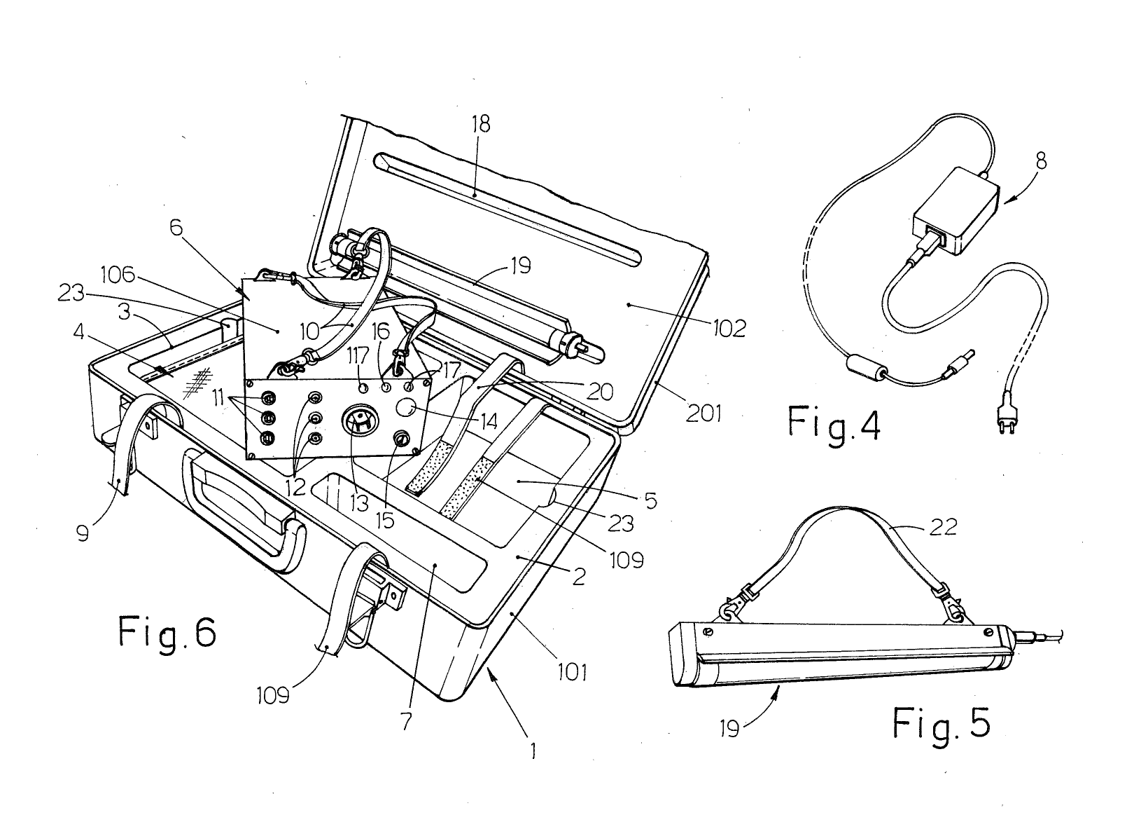

FIG. 4 shows a perspective view of a power supply adapter for recharging the supply and storage unit using the normal electricity mains;

FIG. 5 shows one of the lamp holders with associated lamp, housed inside the case;

FIG. 6 shows the supply and storage unit extracted from its housing seat inside the case and resting on the case.

From FIGS. 1 and 2 it can be seen that the invention envisages the use of any suitable portable container, for example a rigid or semi-rigid case 1, for example of the standard type currently used to contain working equipment, where the base body 101 and the lid 201 have, housed and fixed therein, for example by means of glue, internal padding 2 and 102 which consist of sufficiently elastically yielding soft material and which contain seats for housing and protecting the various components of the device in question. In particular, the padding 2 of the base 101 of the case has three parallelepiped-shaped seats, the biggest seat 3 of which is designed to contain two or more, for example three photovoltaic panels 4 (see below), while the medium-sized seat 5 is designed to contain a supply and storage unit 6 (see below) and the smallest seat 7 is designed to contain a power supply adapter 8 of the type shown for example in FIG. 4, which allows rapid recharging (for example in 3 to 4 hours) of the said supply and storage unit 6 via the normal electricity mains, for example at 220 V.

Pairs of straps 9 and 109, for example with closures of the Velcro or other suitable type, close the compartments 3, 5 and 7 in order to retain the associated aforementioned components inside them.

The photovoltaic panels 4 are of the flexible and folding type and are located inside the four pockets of a flexible containing structure 104 made of flexible and transparent material on the active side of the solar panels and opaque material, for example fabric, on the opposite side, all of which in such a way that this structure may be folded onto itself in book form and wallet form, for example in accordance with the sequence indicated in FIG. 3 by the arrows F1 and F2, so as to form a compact structure which has the size of one of the four pockets of the structure 104 and which may be housed flat inside the compartment 3 of the case 1, together with other two panels 4 of the same type. A flap 204 is hinged on the outer short side of one of the pockets of the structure 104 and accommodates the bundle of bipolar electric wire 304 with quick-action connector for connecting the solar panel to the supply and storage unit 6 (see below) and the said flap 204 may be closed using Velcro inserts or other suitable rapid-action means, on a corresponding portion of the rear opaque part of the structure 104 so as to keep the panel 4 in the compact and stowed-away position inside the compartment 3. It is clear from FIG. 3 how, owing to the presence of three photovoltaic panels 4 with a large surface area, the time needed to recharge the supply and storage unit 6 may be very short, for example varying from 4 to 8 hours, depending on the amount of sunshine available. By providing several photovoltaic panels 4 it is possible to ensure that at least one of these solar recharging means is available even in the event of failure of the remaining ones.

The supply and storage unit 6 shown in FIG. 6 comprises a set of the latest generation batteries, for example lithium ion batteries, with a high capacity, for example in the region of about 25 Ah. The unit 6 is therefore formed by a parallelepiped-shaped metal container 106 with dimensions suitable for being housed inside said compartment 5 and suitably designed to contain safely the said electric batteries and dissipate the heat produced by them during charging and discharging and this container is preferably equipped with shoulder straps 10 which have spring-catch or other types of fasteners, suitable for handling, transporting and hanging the unit 6 from any suitable support means, also of an improvised nature. The following are present on the front side of the unit 6: three input sockets 11 for connection to the three solar panels 4 according to FIG. 3 or to the output of the power supply adapter 8 shown in FIG. 4; three sockets 12 for connection to corresponding user applications for example operating at 12 V dc and with a power of not more than 25 W; at least one socket 13 of the vehicle cigarette lighter type for allowing connection thereto of any user application designed for such a connection and for example also operating at 12 V dc and with a power of not more than 25 W; an ON/OFF pushbutton or switch 14; a fuse-holder cartridge 15; a lamp 16 which indicates when the apparatus is in operation and further differently coloured lamps 17 and 117 for indicating when the unit 6 is recharging and when it has completed charging. From FIGS. 1, 2 and 6 it can be seen that the padding 102 of the lid 201 of the case has three seats 18 which are for example horizontal and which are able to house corresponding lamp holders 19 with an associated lamp, for example of the fluorescent low-consumption type or other suitable type, for example comprising LEDs, and the same lamp holders are held in position by pairs of straps 20 with a Velcro or other type of closure. In FIG. 1, 21 denotes the bundle of cables with quick-action connectors at their ends, useful for connecting the lamp holders 19 to the corresponding outputs 12 of the unit 6 according to FIG. 6. From the detail in FIG. 5 it can be seen that the lamp holders 19 may also be advantageously provided with at least one shoulder strap 22 with spring-catch or other types of fasteners, useful for facilitating handling, transport and hanging of the said lamp holder from any support structure.

In FIGS. 1, 2 and 6, 23 denotes small lateral and vertical recesses in the seats 3 and 5, which are useful for facilitating extraction of the units housed in them and also for ensuring free circulation of air when these seats are occupied or empty.

1. Case or other portable container, with at least one electric power supply and storage unit which can be recharged using solar energy or other energy sources, useful for providing electric power during open-air activities or for other uses, of the type which comprises a preferably rigid or semi-rigid case (1) or other suitable container, with the base body (101) and the lid (201) designed internally to house at least one solar panel and at least one electric power supply and storage unit (6) which can be recharged by means of said solar panel and is provided with sockets for being able to power electrical user applications, characterized in that said case or container (1) houses internally several solar panels (4) which can be folded in order to reduce the space occupied so that in the folded position the said panels occupy an extremely small amount of space and may be easily housed inside the said container (1) and in the open position the said panels have a very large exposed area, all of which being envisaged such that, also owing to the fact that more than one of said solar panels (4) is available, it is possible to reduce substantially the recharging time of said supply and storage unit (6) and this unit may be used with a capacity such as to ensure good autonomy and safe operation thereof.

2. Case according to claim 1, wherein each solar panel (4) can be folded both in book form and in wallet form and is provided on the perimeter with a flap (204) accommodating in bundle form the cable (304) for connection to the supply and storage unit and this flap being provided with Velcro inserts or other suitable means so that it can be fixed rapidly and removably to a rear part of the structure (104) of the panel (4) when folded, so as to keep the said solar panel (4) in the closed and reduced-volume position.

3. Case according to the claim 1, wherein the solar panels (4) of the aforementioned type, for example three of these panels (4) may be stacked and stowed away inside a housing seat (3) provided for example in an internal padding (2) of the bottom body (101) of the said case (1) and straps (9) preferably with a Velcro or other type of closure are provided for keeping the solar panels (4) inside said seat.

4. Case according to claim 3, wherein a seat (5) for housing the supply and storage unit (6) and a seat (7) for housing a unit (8) for rapidly recharging said supply and storage unit via the electricity mains are provided alongside the said seat (3) for housing the solar panels (4), there being provided straps (109) preferably with a Velcro or other type of closure for keeping these units (6, 8) inside the respective housing seats (5, 7).

5. Case according to claim 1, wherein the supply and storage unit (6) is provided with shoulder straps (10) with spring-catch or other types of fasteners, useful for handling, transporting and hanging this unit (6) from any suitable support means, also of an improvised nature.

6. Case according to claim 1, wherein the supply and storage unit (6) is provided on at least one wall: with several input sockets (11) for connection to the solar panels (4) or to the output of the rapid power supply adapter (8); with several sockets (12) for connection to corresponding user applications; with at least one socket (13) of the vehicle cigarette lighter type, for allowing the connection thereto of any user application designed for such a connection; an ON/OFF pushbutton or switch (14); a fuse-holder cartridge (15); a lamp (16) which indicates when the apparatus is in operation and further differently coloured lamps (17, 117) for indicating when the supply and storage unit (6) is recharging and when it has completed charging.

7. Case according to claim 1, wherein an internal padding (102) of the lid (201) of the said case or container (1) has seats (18) for housing corresponding lamp holders with lamp (19) which are kept in position by pairs of straps (20) with a Velcro or other suitable type of closure.

8. Case according to claim 7, wherein the lamp holder with lamp (19) may be provided with at least one shoulder strap (22) with spring-catch or other types of fasteners, useful for facilitating handling, transport and hanging of the said lamp holder from any support structure.
